(19) United States
(12) Patent Application Publication
(10) Pub. No.: US 2026/0351513 A1
(43) Pub. Date: Nov. 5, 2026

(54) MICROSCOPE DEVICE

(71) Applicant: HAMAMATSU PHOTONICS K.K., Hamamatsu-shi, Shizuoka (JP)

(72) Inventors: Daisuke OISHI, Shizuoka (JP); Akira TAKEDA, Shizuoka (JP)

(73) Assignee: HAMAMATSU PHOTONICS K.K., Hamamatsu-shi, Shizuoka (JP)

(21) Appl. No.: 19/485,799

(22) PCT Filed: May 20, 2024
(86) PCT No.: PCT/JP2024/018547

§ 371 Date: Nov. 19, 2025

(30) Foreign Application Priority Data
May 22, 2023 (JP) 2023-084003

(51) Int. Cl. H01J 37/22; H01J 37/28; H01J 37/305

(52) U.S. Cl. CPC H01J 37/226; H01J 37/28; H01J 37/3056; H01J 2237/002; H01J 2237/2482; H01J 2237/31749

(57) ABSTRACT

A microscope device includes a disposition unit on which a sample is disposed; a beam irradiation unit for irradiating the sample, which is disposed on the disposition unit, with a focused ion beam; a laser output unit for outputting laser light having ultrashort pulses; a laser irradiation unit for irradiating the sample, which is disposed on the disposition unit, with the laser light output from the laser output unit; and a microscope unit for observing the sample disposed on the disposition unit. The laser irradiation unit includes a spatial light modulator for modulating the laser light output from the laser output unit and emitting the modulated laser light, and a scanning unit for irradiating the sample, which is disposed on the disposition unit, with the laser light emitted from the spatial light modulator while scanning the sample.

### TECHNICAL FIELD

The present disclosure relates to a microscope device.

### BACKGROUND ART

Patent Literature 1 describes a focused ion beam processing device. In this device, an ion beam column, an electron beam column, a secondary electron detector, a backscattered electron detector, and a sample stage are provided inside a vacuum chamber. In this device, when a sample is processed, a shut-off valve inside the ion beam column is opened, and an ion beam emitted from an ion source is focused on a surface of the sample. In addition, when a processed cross section is observed, electron beams emitted from an electron gun inside the electron beam column are converged to scan the surface of the sample, and backscattered electrons generated by the sample are detected by the backscattered electron detector to form an image.

### CITATION LIST

### Patent Literature

Patent Literature 1: Japanese Unexamined Patent Publication No. 2003-157792

### SUMMARY OF INVENTION

### Technical Problem

By the way, in recent years, in the processing device as described above, a region of an observation target has expanded, and there is a demand for performing large-area processing. In contrast, focused ion beam processing enables high-precision processing, whereas focused ion beam processing is not suitable for large-area processing. Therefore, in the processing device as described above, it has been difficult to observe an expanded region of the observation target.

An object of the present disclosure is to provide a microscope device that enables observation of an expanded region of an observation target through high-precision and large-area processing.

### Solution to Problem

A microscope device according to the present disclosure is [1] “a microscope device including: a disposition unit on which a sample is disposed; a beam irradiation unit configured to irradiate the sample, which is disposed on the disposition unit, with a focused ion beam; a laser output unit configured to output laser light having ultrashort pulses; a laser irradiation unit configured to irradiate the sample, which is disposed on the disposition unit, with the laser light output from the laser output unit; and a microscope unit configured to observe the sample disposed on the disposition unit. The laser irradiation unit includes a spatial light modulator configured to modulate the laser light output from the laser output unit and emitting the modulated laser light, and a scanning unit configured to irradiate the sample, which is disposed on the disposition unit, with the laser light emitted from the spatial light modulator while scanning the sample”.

The microscope device includes the beam irradiation unit for irradiating the sample with a focused ion beam, and the microscope unit for observing the sample. Therefore, the sample can be processed and observed with high precision by processing the sample using a focused ion beam. In addition, the microscope device includes the laser output unit and a laser optical system for irradiating the sample with the laser light having ultrashort pulses. Accordingly, the sample can be processed using the laser light. Laser processing enables processing over a large area with high throughput compared to processing using a focused ion beam. Therefore, according to the microscope device, an expanded region can be observed through high-precision and large-area processing. Incidentally, by using laser processing, thermal influence on the sample can be reduced, and a clean processed cross section can also be acquired.

Furthermore, in the microscope device, since the laser optical system includes the spatial light modulator, the laser light with which the sample is irradiated can be modulated in various manners. Accordingly, for example, by changing the beam pattern of the laser light with which the sample is irradiated, the processed cross section can be flattened and the processing speed can be increased, or the focal position of the laser light with respect to the sample can be changed. To change the beam pattern of the laser light, for example, the use of a diffractive optical element (DOE) can also be considered; however, in this case, it is necessary to move a movable stage including the DOE, and vibrations associated with mechanical operation are generated and affect the observation of a microscopic region using the microscope unit, which is a risk. In contrast, in the microscope device, by using the spatial light modulator when changing the beam pattern, the generation of the vibrations can be suppressed, and the influence of the vibrations on the observation of the microscopic region using the microscope unit can be reduced.

A microscope device according to the present disclosure may be [2] “the microscope device according to [1] above, in which the spatial light modulator modulates the laser light to change a beam pattern of the laser light”. In such a manner, the beam pattern of the laser light in an irradiation region can be changed using the spatial light modulator.

A microscope device according to the present disclosure may be [3] “the microscope device according to [2] above, in which the spatial light modulator modulates the laser light such that the beam pattern of the laser light in an irradiation region has a peak of beam intensity that surrounds a center of the irradiation region”. In this case, the flatness of the processed cross section can be improved.

A microscope device according to the present disclosure may be [4] “the microscope device according to [3] above, in which the spatial light modulator modulates the laser light such that the beam pattern has the peak of the beam intensity that annularly surrounds the center of the irradiation region”. In this case, the flatness of the processed cross section can be reliably improved.

A microscope device according to the present disclosure may be [5] “the microscope device according to [3] above, in which the spatial light modulator modulates the laser light such that the beam pattern has a plurality of the peaks of the beam intensity that surround the center of the irradiation region”. In this case, the flatness of the processed cross section can be reliably improved.

A microscope device according to the present disclosure may be [6] “the microscope device according to any one of [3] to [5] above, in which the spatial light modulator modulates the laser light such that the beam pattern has the peak of the beam intensity at the center of the irradiation region”. In such a manner, the beam pattern of the laser light may also be changed to have a peak of beam intensity at the center of the irradiation region.

A microscope device according to the present disclosure may be [7] “the microscope device according to any one of [1] to [6] above, in which the spatial light modulator modulates the laser light such that a beam pattern of the laser light in an irradiation region is switched between one beam pattern and another beam pattern different from the one beam pattern”. In this case, for example, appropriate processing can be achieved by modulating the laser light to produce different beam patterns in two cases with different requirements, such as a first case in which an improvement in processing efficiency is required and a second case in which the flatness of the processed cross section is required.

A microscope device according to the present disclosure may be [8] “the microscope device according to any one of [1] to [7] above further including: a first chamber that accommodates the beam irradiation unit and the microscope unit; and a second chamber formed with an incident portion for the laser light is formed”. In such a manner, by using the second chamber (that is, a chamber for laser processing) in which the incident portion for the laser light is formed, separately from the first chamber that accommodates the beam irradiation unit and the microscope unit, the influence of particles generated during laser processing on the beam irradiation unit and the microscope unit or the influence of vibrations generated during laser processing on the microscope unit can be suppressed.

A microscope device according to the present disclosure may be [9] “the microscope device according to any one of [1] to [7] further including: a chamber which accommodates the beam irradiation unit and the microscope unit, and formed with an incident portion for the laser light is formed”. In this case, processing with a focused ion beam, observation using the microscope unit, and processing with the laser light can be performed inside the same chamber. Therefore, movement of the sample at each stage becomes unnecessary, so that high-accuracy processing and observation can be performed.

A microscope device according to the present disclosure may be [10] “the microscope device according to [9] above further including: a cover that is provided between the beam irradiation unit and the disposition unit and/or between the microscope unit and the disposition unit, and that transmits the laser light”. In this case, when processing with a focused ion beam, observation using the microscope unit, and processing with the laser light are performed inside the same chamber, the adhesion of particles generated during laser processing to the beam irradiation unit and/or the microscope unit can be suppressed.

A microscope device according to the present disclosure may be [11] “the microscope device according to any one of [1] to [10] above, in which the microscope unit is at least a part of a scanning electron microscope”. In this case, a microscopic region can be observed using the scanning electron microscope.

A microscope device according to the present disclosure may be [12] “the microscope device according to any one of [1] to [11] above, in which the p-polarized laser light is incident on the spatial light modulator”. In this case, the laser light can be effectively modulated by the spatial light modulator.

A microscope device according to the present disclosure may be [13] “the microscope device according to any one of [1] to [12] above, in which the collimated laser light is incident on the spatial light modulator”. In this case, the laser light can be effectively modulated by the spatial light modulator.

A microscope device according to the present disclosure may be [14] “the microscope device according to any one of [1] to [13] above, in which the laser irradiation unit includes an adjustment unit that is disposed between the spatial light modulator and the laser output unit, and that adjusts an output and/or a beam diameter of the laser light”. In this case, the output and/or the beam diameter of the laser light can be adjusted.

A microscope device according to the present disclosure may be [15] “the microscope device according to any one of [1] to [14] further including: a cooling portion configured to cool the spatial light modulator”. In this case, thermal influence on the spatial light modulator is suppressed.

A microscope device according to the present disclosure may be [16] “the microscope device according to any one of [1] to [15] above, in which the scanning unit is an optical element that receives an incidence of the laser light emitted from the spatial light modulator, and that emits the laser light so as to irradiate the sample disposed on the disposition unit while scanning the sample. The laser irradiation unit includes a relay optical system that is disposed between the spatial light modulator and the scanning unit, and that transfers an image of the laser light modulated by the spatial light modulator”. In this case, a desired beam pattern can be suitably formed in the irradiation region of the laser light.

### Advantageous Effects of Invention

According to the present disclosure, it is possible to provide the microscope device that enables observation of an expanded region of an observation target through high-precision and large-area processing.

### BRIEF DESCRIPTION OF DRAWINGS

FIG. 1 is a schematic view showing a part of a microscope device according to the present embodiment.

FIG. 2 is a schematic view showing the remaining portion of the microscope device shown in FIG. 1.

FIG. 3 is a schematic view for describing the formation of LIPSS on a processed cross section.

FIG. 4 is a view showing processing with a Gaussian beam.

FIG. 5 is a view showing processing when the beam pattern is adjusted.

FIG. 6 is a schematic view showing an example of a beam pattern.

### DESCRIPTION OF EMBODIMENTS

Hereinafter, a microscope device according to one embodiment will be described with reference to the drawings. Incidentally, in the description of the drawings, the same or corresponding elements are denoted by the same reference signs, and duplicate descriptions may be omitted.

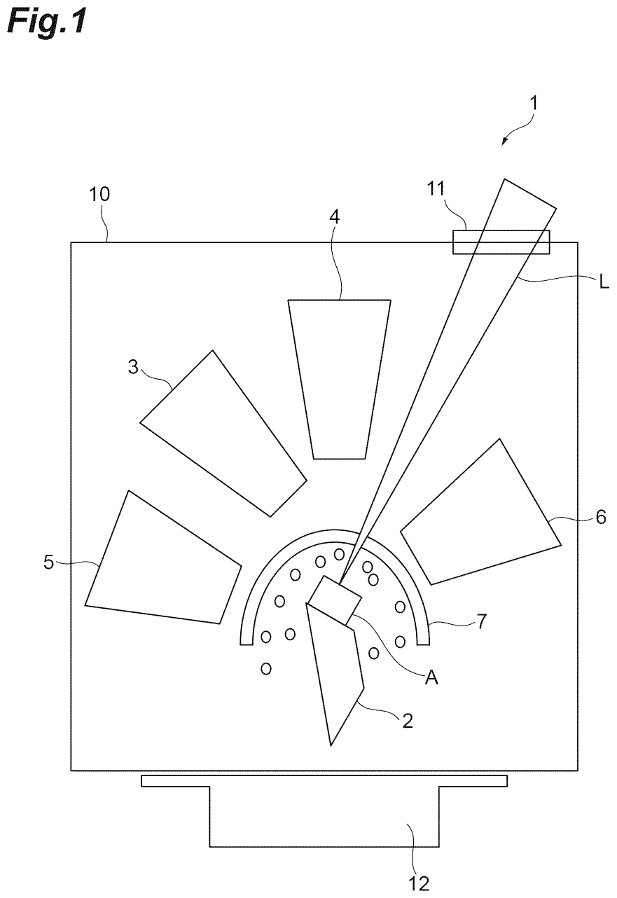

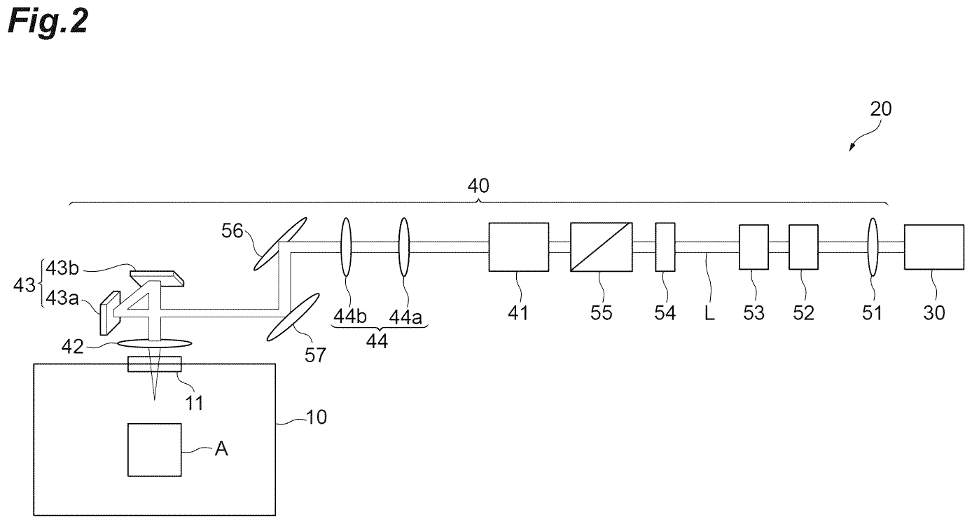

FIG. 1 is a schematic view showing a part of a microscope device according to the present embodiment. FIG. 2 is a schematic view showing the remaining portion of the microscope device shown in FIG. 1. A microscope device 1 shown in FIGS. 1 and 2 is, as will be described later, a device that includes a focused ion beam (FIB) device that performs etching on a sample by irradiating the sample with focused ions (for example, Ga ions); a scanning electron microscope (SEM) device that observes the sample by irradiating the sample with an electron beam; and a laser device that performs laser processing (for example, ablation processing) on the sample by irradiating the sample with laser light, and that enables, by means of the SEM device, observation of a processed cross section of the sample formed by processing performed by the FIB device and/or the laser device.

The microscope device 1 includes a sample holder (disposition unit) 2, a beam irradiation unit 3, a first microscope unit (microscope unit) 4, a second microscope unit (microscope unit) 5, a cover 7, a chamber 10, and a laser device 20. Sample A is disposed on the sample holder 2. The sample holder 2 may support the sample A without fixing the sample A as in a case in which the sample A is simply placed, or may fix and hold the sample A, for example, through affixing or the like. Here, the sample holder 2 holds the sample A. The beam irradiation unit 3 serves to irradiate the sample A held (disposed) (hereinafter, the same) by the sample holder 2 with a focused ion beam. Therefore, the beam irradiation unit 3 may include at least a focused ion beam emission unit of the FIB device.

The first microscope unit 4 serves to observe the sample A held by the sample holder 2. More specifically, the first microscope unit 4 is configured to be able to acquire an image of the sample A (observe the sample A) by irradiating the sample A held by the sample holder 2 with an electron beam, and detecting secondary electrons or the like generated in the sample A. Therefore, the first microscope unit 4 may be at least a part of the SEM device that includes an electron beam emission unit and a detection unit.

Similarly to the first microscope unit 4, the second microscope unit 5 serves to observe the sample A held by the sample holder 2. More specifically, the second microscope unit 5 can acquire information on the crystal structure or the like of the sample A (observe the sample A) by irradiating the sample A held by the sample holder 2 with an electron beam, and detecting the electron beam scattered by the sample A. That is, as one example, the second microscope unit 5 is a part of the SEM device using an electron backscatter diffraction (EBSD) method, and may be a part of the SEM device including at least an electron beam emission unit and a detection unit. Incidentally, the microscope device 1 may include a transmission electron microscope (TEM) device instead of (or in addition to) the SEM device. In this case, the first microscope unit 4 and the second microscope unit 5 may be at least a part of the TEM device.

The cover 7 is made of a material that transmits laser light L to be described later, and is provided to cover the sample A held by the sample holder 2. Accordingly, the cover 7 may be disposed at a reference position interposed between the sample holder 2 and the beam irradiation unit 3, the first microscope unit 4, and the second microscope unit 5 in the optical path of the laser light L. Incidentally, the cover 7 is configured to be movable from the reference position such that the cover 7 is not interposed between the sample holder 2 and the beam irradiation unit 3, the first microscope unit 4, and the second microscope unit 5.

The chamber 10 accommodates the sample holder 2, the beam irradiation unit 3, the first microscope unit 4, the second microscope unit 5, and the cover 7. An incident portion 11 for the laser light L that is formed in a window shape from a material that transmits the laser light L is formed in the chamber 10. In addition, an evacuation portion 12 for depressurization (creating a vacuum) by evacuation of the inside of the chamber 10 is formed in the chamber 10. Furthermore, another unit 6 for processing or observing the sample A held by the sample holder 2 may be provided inside the chamber 10.

The laser device 20 includes a laser output unit 30 and a laser optical system 40. The laser output unit 30 serves to output the laser light L having ultrashort pulses at low fluence. The pulse width of the laser light L output from the laser output unit 30 is, for example, 1 ps or less. In addition, as one example, the fact that the laser light L has low fluence may indicate that the energy density of the laser light L is an energy density in the vicinity of a processing threshold value of the sample A, which is determined such that ablation processing is induced during laser processing of the sample A. The laser optical system 40 is a laser irradiation unit for irradiating the sample A held by the sample holder 2 with the laser light L output from the laser output unit 30. The laser light L output from the laser output unit 30 is guided by the laser optical system 40, and is incident into the chamber 10 through the incident portion 11.

The laser optical system 40 includes a spatial light modulator 41 and a galvanometer mirror (scanning unit) 43. The spatial light modulator 41 modulates the laser light L output from the laser output unit 30 in accordance with a modulation pattern, and emits the modulated laser light L. More specifically, the spatial light modulator 41 is, for example, a liquid crystal on silicon-spatial light modulator (LCOS-SLM), and displays a modulation pattern on a liquid crystal layer, thereby modulating the laser light L, which is incident on and emitted from the liquid crystal layer, in accordance with the modulation pattern.

The galvanometer mirror 43 includes mirrors 43a and 43b, and irradiates the sample A held by the sample holder 2 with the laser light L emitted from the spatial light modulator 41, while scanning the sample A by driving the mirrors 43a and 43b. In such a manner, in the present embodiment, the laser optical system 40 includes, as a scanning unit, the galvanometer mirror 43 which is an optical element that receives the incidence of the laser light L emitted from the spatial light modulator 41 and that emits the laser light L so as to irradiate the sample A held by the sample holder 2 while scanning the sample A. Incidentally, instead of (or in addition to) the galvanometer mirror, the laser irradiation unit may include, as a scanning unit, a configuration for mechanically moving the sample holder 2 (that is, the sample A) so as to irradiate the sample A with the laser light emitted from the spatial light modulator 41 while scanning the sample A. The laser light L emitted from the galvanometer mirror 43 is focused toward the sample A by a lens 42. The lens 42 is, for example, an fθ lens.

The laser optical system 40 includes a relay optical system 44. The relay optical system 44 is disposed between the spatial light modulator 41 and the galvanometer mirror 43. The relay optical system 44 includes a pair of lenses 44a and 44b, and serves to transfer an image of the laser light L modulated by the spatial light modulator 41 onto the lens 42. The optical path of the laser light L emitted from the spatial light modulator 41 and passing through the relay optical system 44 is adjusted by predetermined mirrors 56 and 57, and the laser light L is then provided to the galvanometer mirror 43.

The laser optical system 40 further includes a collimating lens 51, an output control unit (adjustment unit) 52, a beam diameter control unit (adjustment unit) 53, a half-wave plate 54, and a polarizing beam splitter 55 that are disposed in order on the optical path of the laser light L from the laser output unit 30 toward the spatial light modulator 41. The collimating lens 51 collimates the laser light L output from the laser output unit 30, and emits the collimated laser light L. Therefore, the collimated laser light L is incident on the spatial light modulator 41. The collimating lens 51 may be omitted.

The output control unit 52 is, for example, an attenuator, and adjusts the output of the laser light L output from the laser output unit 30. The beam diameter control unit 53 is, for example, a beam expander, and adjusts the beam diameter of the laser light L output from the laser output unit 30. In such a manner, the output control unit 52 and the beam diameter control unit 53 are disposed between the spatial light modulator 41 and the laser output unit 30, and function as the adjustment units that adjust the output and beam diameter of the laser light L.

The half-wave plate 54 changes the polarization direction of the laser light L output from the laser output unit 30. The polarizing beam splitter 55 splits the laser light L, which is output from the laser output unit 30 and is incident through the half-wave plate 54, into an s-polarized component and a p-polarized component. The p-polarized component (p-polarized laser light L) is incident on the spatial light modulator 41. As described above, the laser light L incident on the spatial light modulator 41 is modulated and then incident into the chamber 10 through the galvanometer mirror 43, and is provided for scanning of the sample A.

In the microscope device 1 described above, the processing of the sample A using a focused ion beam from the beam irradiation unit 3 and the processing of the sample A using the laser light L from the laser device 20 can be performed. When a focused ion beam is used, the sample A can be processed with high accuracy. On the other hand, when the laser light L is used, a large area of the sample A can be processed with high throughput.

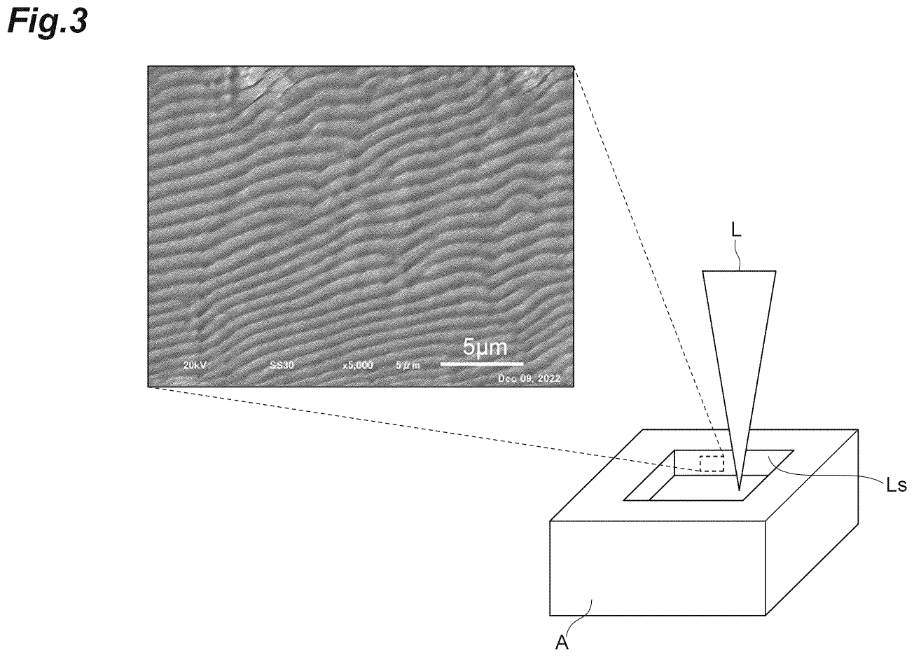

Here, as shown in FIG. 3, when the sample A is processed using the laser light L having ultrashort pulses at low fluence in the vicinity of a processing threshold value of the sample A, a laser induced periodic surface structure (LIPSS) may be formed on a processed cross section Ls of the sample A. For observation using the SEM device, flatness of the processed cross section Ls is required, and the formation of LIPSS on the processed cross section Ls is not preferred.

As a method for reducing LIPSS on the processed cross section Ls, a method using circularly polarized light can be considered; however, circularly polarized light is a combination of p-polarized light and s-polarized light, and the absorptance (processing rate) of the sample A for the laser light L decreases compared to that of linearly polarized light (p-polarized light). In addition, in the laser optical system 40 described above, when the laser light L is scanned over a wide range of the sample A using the galvanometer mirror 43, it can be considered that the incident position of the laser light L on the lens 42 deviates from the center of the lens 42. Therefore, when circularly polarized light is used, the polarized light becomes elliptical at an end portion of the lens 42, and therefore, a decrease in processing quality such as insufficient reduction of LIPSS occurs, which is a risk.

As one hypothesis for the principle of LIPSS formation, it has been proposed that LIPSS is due to the interaction between plasma and laser light. The outline of the hypothesis is as follows. That is, when a sample is irradiated with laser light having ultrashort pulses, atoms and ions are removed from the surface of the sample. When the atoms and ions are removed, plasma having a shielding effect is generated directly above the irradiation point of the laser light. Accordingly, the atoms and ions removed from the surface of the sample are deposited on a processed cross section without being diffused due to the shielding effect of the plasma. As a result, LIPSS is formed on the processed cross section due to the deposits.

In contrast, the inventors have found that LIPSS can be reduced by controlling the beam pattern of the laser light L in the irradiation region of the laser light L on the sample A. Subsequently, this point will be described.

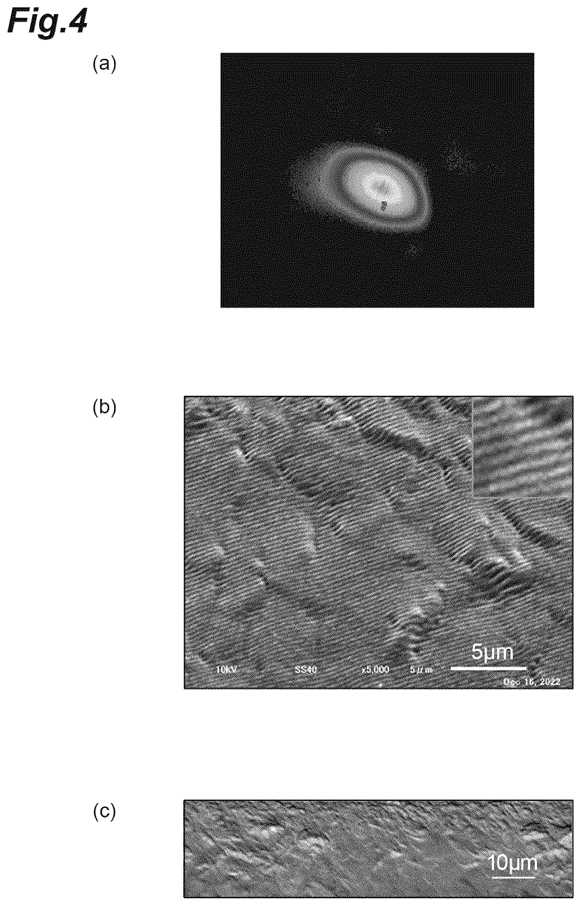

FIG. 4 is a view showing processing with a Gaussian beam. (a) in FIG. 4 shows a beam profile of a Gaussian beam, (b) in FIG. 4 shows an SEM image (secondary electron image) of a processed cross section after processing with the Gaussian beam, and (c) in FIG. 4 shows an SEM image (backscattered electron image) of the processed cross section after processing with the Gaussian beam. As shown in FIG. 4, when processing is performed using the laser light that is a Gaussian beam, LIPSS is formed on the processed cross section (see (b) in FIG. 4), and irregularities are formed on the processed cross section even on a scale larger than that of the LIPSS (see (c) in FIG. 4).

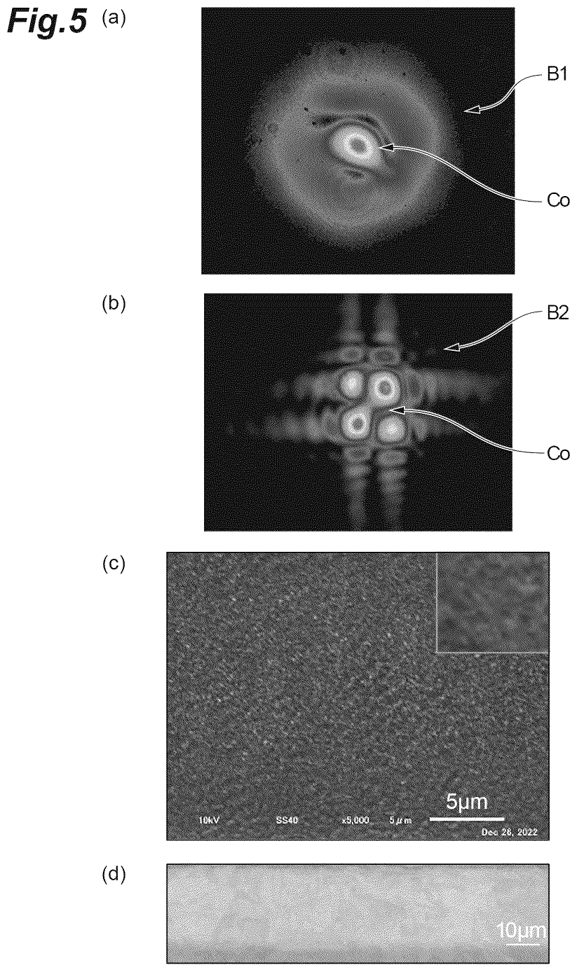

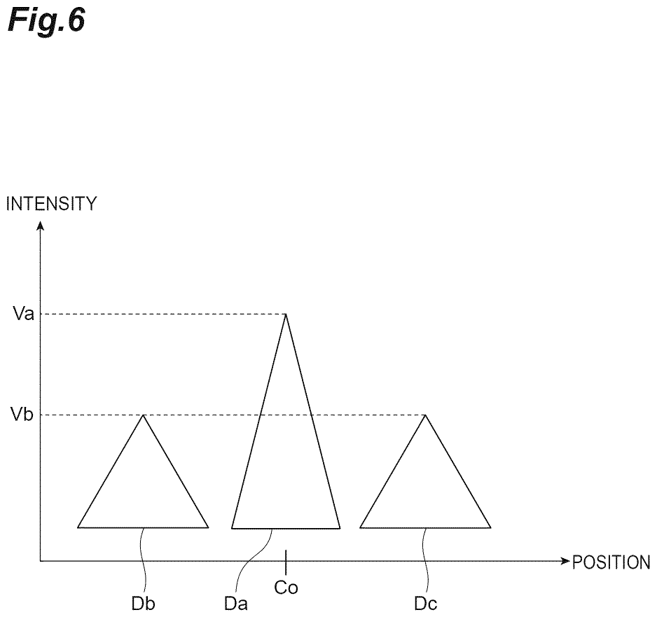

FIG. 5 is a view showing processing when the beam pattern is adjusted. (a) in FIG. 5 shows one example of a beam profile of the laser light L after the beam pattern is adjusted, and (b) in FIG. 5 shows another example of a beam profile of the laser light L after the beam pattern is adjusted. In both cases, as shown in FIGS. 5 and 6, the beam pattern includes regions Db and Dc having a peak Vb of beam intensity so as to surround a center Co of the irradiation region of the laser light L.

The example in (a) of FIG. 5 shows a beam pattern B1 having the peak Vb of beam intensity that annularly surrounds the center Co, and the example in (b) of FIG. 5 shows a beam pattern B2 having a plurality of the peaks Vb of beam intensity so as to (intermittently) surround the center Co. In addition, the beam pattern B1 includes a region Da having a peak Va (here, peak Va >peak Vb) of beam intensity at the center Co. On the other hand, in this example, the beam pattern B2 does not have a peak of beam intensity at the center Co (may have).

In such a manner, by adjusting the beam pattern of the laser light L, that is, by setting the beam pattern of the laser light L to the beam patterns B1 and B2, it is understood that as shown in (c) of FIG. 5, LIPSS on the processed cross section is suppressed, and as shown in (d) of FIG. 5, the processed cross section is flattened even on a scale larger than that of the LIPSS.

Based on the above finding, it can be considered that the formation of LIPSS can be suppressed by adjusting the beam pattern of the laser light L; however, various methods for adjusting the beam pattern of the laser light L can be considered. As one example of adjusting the beam pattern of the laser light L, for example, the use of a diffractive optical element (DOE) can also be considered; however, in this case, it is necessary to move a movable stage including the DOE, and vibrations associated with mechanical operation are generated and may affect the observation of a microscopic region using the first microscope unit 4 and the second microscope unit 5.

Therefore, in the microscope device 1 according to the present embodiment, the beam pattern of the laser light L is adjusted using the spatial light modulator 41. That is, in the microscope device 1, the spatial light modulator 41 modulates the laser light L to change the beam pattern of the laser light L. More specifically, the spatial light modulator 41 can modulate the laser light L1 such that the beam pattern of the laser light L in the irradiation region becomes the beam pattern B1 having the peak Vb of beam intensity that annularly surrounds the center Co of the irradiation region.

Alternatively, the spatial light modulator 41 can modulate the laser light L such that the beam pattern of the laser light L in the irradiation region becomes the beam pattern B2 having the plurality of peaks Vb of beam intensity so as to surround the center Co of the irradiation region. In addition, the spatial light modulator 41 can modulate the laser light L such that the beam pattern B1 has the peak Va of beam intensity at the center Co of the irradiation region of the laser light L. In addition, the spatial light modulator 41 may also modulate the laser light L such that the beam pattern B2 has a peak of beam intensity at the center Co of the irradiation region of the laser light L.

Furthermore, the spatial light modulator 41 may modulate the laser light L such that the beam pattern of the laser light L in the irradiation region is switched between one beam pattern (for example, the beam pattern B1 or the beam pattern B2) and another beam pattern different from the one beam pattern (for example, a beam pattern different from the beam pattern B1 or the beam pattern B2).

Incidentally, the spatial light modulator 41 may modulate the laser light L to correct aberrations occurring when the laser light L passes through the transmissive member such as the cover 7 or the incident portion 11. Accordingly, the expansion of the spot diameter at the focal position of the laser light L can be suppressed.

As described above, the microscope device 1 includes the beam irradiation unit 3 for irradiating the sample A with a focused ion beam, and the first microscope unit 4 and the second microscope unit 5 for observing the sample A. Therefore, the sample A can be processed and observed with high precision by processing the sample A using a focused ion beam. In addition, the microscope device 1 includes the laser output unit 30 and the laser optical system 40 for irradiating the sample A with the laser light L having ultrashort pulses. Accordingly, the sample A can be processed using the laser light L. Laser processing enables processing over a large area with high throughput compared to processing using a focused ion beam. Therefore, according to the microscope device 1, an expanded region can be observed through high-precision and large-area processing. Incidentally, by using laser processing, thermal influence on the sample A can be reduced, and a clean processed cross section can also be acquired.

Furthermore, in the microscope device, since the laser optical system includes the spatial light modulator 41, the laser light L with which the sample A is irradiated can be modulated in various manners. Accordingly, for example, the processed cross section can be flattened by changing the beam pattern of the laser light L with which the sample is irradiated, and suppressing LIPSS or the like as described above. In addition, by changing the beam pattern of the laser light L, the processing speed can be increased, or the focal position of the laser light L with respect to the sample can be changed.

As described above, to change the beam pattern of the laser light L, for example, the use of a diffractive optical element (DOE) can also be considered; however, in this case, it is necessary to move a movable stage including the DOE, and vibrations associated with mechanical operation are generated and affect the observation of a microscopic region using the first microscope unit 4 and the second microscope unit 5, which is a risk. In contrast, in the microscope device 1, by using the spatial light modulator 41 when changing the beam pattern, the generation of the vibrations can be suppressed, and the influence of the vibrations on the observation of the microscopic region using the first microscope unit 4 and the second microscope unit 5 can be reduced.

In addition, in the microscope device 1, the spatial light modulator 41 can modulate the laser light L to change the beam pattern of the laser light L. In such a manner, the beam pattern of the laser light L in the irradiation region can be changed using the spatial light modulator 41.

In addition, in the microscope device 1, the spatial light modulator 41 can modulate the laser light L such that the beam pattern of the laser light L in the irradiation region has the peak Vb of beam intensity that surrounds the center Co of the irradiation region.

Therefore, the flatness of the processed cross section can be improved by suppression of LIPSS or the like.

In addition, in the microscope device 1, the spatial light modulator 41 can modulate the laser light L such that the beam pattern of the laser light L in the irradiation region has the peak Vb of beam intensity that annularly surrounds the center Co of the irradiation region. Therefore, the flatness of the processed cross section can be improved by suppression of LIPSS or the like.

In addition, in the microscope device 1, the spatial light modulator 41 can modulate the laser light L such that the beam pattern of the laser light L in the irradiation region has the plurality of peaks Vb of beam intensity that surround the center Co of the irradiation region. In this case as well, the flatness of the processed cross section can be improved by suppression of LIPSS or the like.

In addition, in the microscope device 1, the spatial light modulator 41 can modulate the laser light L such that the beam pattern of the laser light L in the irradiation region has the peak Va of beam intensity at the center Co of the irradiation region. In such a manner, the beam pattern of the laser light L may also be changed to have the peak Va of beam intensity at the center Co of the irradiation region.

In addition, in the microscope device 1, the spatial light modulator 41 can modulate the laser light L such that the beam pattern of the laser light L in the irradiation region is switched between one beam pattern and another beam pattern different from the one beam pattern. Therefore, for example, appropriate processing can be achieved by modulating the laser light L to produce different beam patterns in two cases with different requirements, such as a first case in which an improvement in processing efficiency is required and a second case in which the flatness of the processed cross section is required.

In addition, the microscope device 1 includes the chamber 10 which accommodates the beam irradiation unit 3, the first microscope unit 4, and the second microscope unit 5, and in which the incident portion 11 for the laser light L is formed. Therefore, processing with a focused ion beam, observation using the first microscope unit 4 and the second microscope unit 5, and processing with the laser light L can be performed inside the same chamber 10. Therefore, movement of the sample A between chambers at each stage becomes unnecessary, so that high-accuracy processing and observation can be performed.

In addition, the microscope device 1 includes the cover 7 that is provided between the beam irradiation unit 3 and the sample holder 2, between the first microscope unit 4 and the sample holder 2, and between the second microscope unit 5 and the sample holder 2, and that transmits the laser light L. Therefore, when processing with a focused ion beam, observation using the first microscope unit 4 and the second microscope unit 5, processing with the laser light L are performed inside the same chamber, the adhesion of particles generated during laser processing to the beam irradiation unit 3, the first microscope unit 4, and the second microscope unit 5 can be suppressed.

In addition, in the microscope device 1, the first microscope unit 4 and the second microscope unit 5 are at least a part of the scanning electron microscope. Therefore, a microscopic region can be observed using the scanning electron microscope.

In addition, in the microscope device 1, the p-polarized laser light L is incident on the spatial light modulator 41. Therefore, the laser light L can be effectively modulated by the spatial light modulator 41.

In addition, in the microscope device 1, the collimated laser light L is incident on the spatial light modulator 41. Therefore, the laser light can be effectively modulated by the spatial light modulator 41.

In addition, in the microscope device 1, the laser optical system 40 includes the adjustment units (the output control unit 52 and beam diameter control unit 53) that are disposed between the spatial light modulator 41 and the laser output unit 30, and that adjust the output and beam diameter of the laser light L. Therefore, the output and beam diameter of the laser light L can be adjusted.

Furthermore, in the microscope device 1, the laser optical system 40 includes the relay optical system 44 that is disposed between the spatial light modulator 41 and the galvanometer mirror 43, and that transfers an image of the laser light L modulated by the spatial light modulator 41. Therefore, a desired beam pattern can be suitably formed in the irradiation region of the laser light L.

The above embodiment has described one aspect of the present invention. Therefore, the present invention is not limited to the embodiment described above, and may be arbitrarily modified. Subsequently, modification examples of the microscope device 1 will be described.

For example, the microscope device 1 may include a first chamber that accommodates the beam irradiation unit 3, the first microscope unit 4, and the second microscope unit 5, and a second chamber in which the incident portion 11 for the laser light L is formed. In this case, by using the second chamber (that is, a chamber for laser processing) in which the incident portion 11 for the laser light L is formed, separately from the first chamber (that is, a chamber for FIB processing and observation) that accommodates the beam irradiation unit or the first microscope unit 4 and the second microscope unit 5, the influence of particles generated during laser processing on the beam irradiation unit 3, the first microscope unit 4, and the second microscope unit 5 or the influence of vibrations generated during laser processing on the first microscope unit 4 and the second microscope unit 5 can be suppressed.

Incidentally, in this case, the first chamber and the second chamber are not limited to being configured as chambers independent of each other, and may be configured by providing a partition or the like in one chamber. In other words, in the microscope device 1, a chamber portion for FIB processing and observation (first chamber) and a chamber portion for laser processing (second chamber) may be configured by partitioning one chamber. In addition, in the microscope device 1, at least a part of the laser device 20 may be disposed inside the chamber 10 (or the second chamber). As one example, the laser output unit 30 and the laser optical system 40 may be disposed inside the chamber 10 (or the second chamber).

In addition, the microscope device 1 may include a cooling portion for cooling the spatial light modulator 41. In this case, thermal influence on the spatial light modulator 41 is suppressed.

In addition, in the microscope device 1, the laser optical system 40 includes the collimating lens 51 for causing the collimated laser light L to be incident on the spatial light modulator 41. However, when collimated light is output from the laser output unit 30, the collimating lens 51 may be omitted.

In addition, in the microscope device 1, one of the first microscope unit 4 and the second microscope unit 5 may be omitted, and it is sufficient that at least one microscope unit is provided. Furthermore, in the microscope device 1, one or both of the output control unit 52 and the beam diameter control unit 53 and the relay optical system 44 can also be omitted.

### REFERENCE SIGNS LIST

1: microscope device, 2: sample holder, 3: beam irradiation unit, 4: first microscope unit (microscope unit), 5: second microscope unit (microscope unit), 7: cover, 10: chamber, 11: incident portion, 30: laser output unit, 40: laser optical system, 41: spatial light modulator, 43: galvanometer mirror (scanning unit), 44: relay optical system, 52: output control unit (adjustment unit), 53: beam diameter control unit (adjustment unit), L: laser light.

1. A microscope device, comprising:
a disposition unit on which a sample is disposed;
a beam irradiation unit configured to irradiate the sample, which is disposed on the disposition unit, with a focused ion beam;
a laser output unit configured to output laser light having ultrashort pulses;
a laser irradiation unit configured to irradiate the sample, which is disposed on the disposition unit, with the laser light output from the laser output unit; and
a microscope unit configured to observe the sample disposed on the disposition unit,
wherein the laser irradiation unit includes
a spatial light modulator configured to modulate the laser light output from the laser output unit and emitting the modulated laser light, and
a scanning unit configured to irradiate the sample, which is disposed on the disposition unit, with the laser light emitted from the spatial light modulator while scanning the sample.

2. The microscope device according to claim 1,
wherein the spatial light modulator modulates the laser light to change a beam pattern of the laser light.

3. The microscope device according to claim 2,
wherein the spatial light modulator modulates the laser light such that the beam pattern of the laser light in an irradiation region has a peak of beam intensity that surrounds a center of the irradiation region.

4. The microscope device according to claim 3,
wherein the spatial light modulator modulates the laser light such that the beam pattern has the peak of the beam intensity that annularly surrounds the center of the irradiation region.

5. The microscope device according to claim 3,
wherein the spatial light modulator modulates the laser light such that the beam pattern has a plurality of the peaks of the beam intensity that surround the center of the irradiation region.

6. The microscope device according to claim 3,
wherein the spatial light modulator modulates the laser light such that the beam pattern has the peak of the beam intensity at the center of the irradiation region.

7. The microscope device according to claim 1,
wherein the spatial light modulator modulates the laser light such that a beam pattern of the laser light in an irradiation region is switched between one beam pattern and another beam pattern different from the one beam pattern.

8. The microscope device according to claim 1, further comprising:
a first chamber that accommodates the beam irradiation unit and the microscope unit; and
a second chamber formed with an incident portion for the laser light is formed.

9. The microscope device according to claim 1, further comprising:
a chamber which accommodates the beam irradiation unit and the microscope unit, and formed with an incident portion for the laser light is formed.

10. The microscope device according to claim 9, further comprising:
a cover that is provided between the beam irradiation unit and the disposition unit and/or between the microscope unit and the disposition unit, and that transmits the laser light.

11. The microscope device according to claim 1,
wherein the microscope unit is at least a part of a scanning electron microscope.

12. The microscope device according to claim 1,
wherein p-polarized laser light is incident on the spatial light modulator.

13. The microscope device according to claim 1,
wherein collimated laser light is incident on the spatial light modulator.

14. The microscope device according to claim 1,
wherein the laser irradiation unit includes an adjustment unit that is disposed between the spatial light modulator and the laser output unit, and that adjusts an output and/or a beam diameter of the laser light.

15. The microscope device according to claim 1, further comprising:
a cooling portion configured to cool the spatial light modulator.

16. The microscope device according to claim 1,
wherein the scanning unit is an optical element that receives an incidence of the laser light emitted from the spatial light modulator, and that emits the laser light so as to irradiate the sample disposed on the disposition unit while scanning the sample, and
the laser irradiation unit includes a relay optical system that is disposed between the spatial light modulator and the scanning unit, and that transfers an image of the laser light modulated by the spatial light modulator.
